(19) United States
(12) Patent Application Publication
(10) Pub. No.: US 2024/0250156 A1
(43) Pub. Date: Jul. 25, 2024

(54) Quantum Dipole Battery

(71) Applicant: Pronoia, Inc., Los Angeles, CA (US)

(72) Inventor: Woo Yong Lie, Los Angeles, CA (US)

(21) Appl. No.: 18/391,643

(22) Filed: Dec. 20, 2023

Related U.S. Application Data
(60) Provisional application No. 63/440,662, filed on Jan. 23, 2023.

(51) Int. Cl. H01L 29/66; H01L 29/15; H01L 29/92

(52) U.S. Cl. CPC H01L 29/66977; H01L 29/152; H01L 29/92

(57) ABSTRACT

A quantum dipole battery includes a positive electrode, a negative electrode, and a multilayer structure, disposed between the positive electrode and the negative electrode. The multilayer structure defines a quantum superlattice made from bilayers with each bilayer including a quantum well layer and a quantum barrier layer. The quantum well layer is separated from and coupled to adjacent quantum well layers by one of the quantum barrier layers. Excitons and indirect excitons are created and adjacent quantum wells and barriers are coupled together with quantum excitonic and ionic dipolar waves through a long range phase correlation. Electronic charges are transported by a phonon-assisted quantum tunneling or a hopping mechanism through the quantum barrier layers and the coupling of adjacent quantum well layers and quantum barrier layers results in a dipole-dipole interaction between excitonic dipoles and ionic dipoles causing Rabi splitting of energy level.

### CROSS-REFERENCE TO RELATED APPLICATIONS

This application claims the benefit of U.S. Provisional Patent Application No. 63/440,662, filed Jan. 23, 2023, which is incorporated by reference.

### BACKGROUND

### 1. Technical Field

The subject matter described relates generally to energy storage and, in particular, to a quantum dipole battery and related discharge control system.

### 2. Background Information

Main use cases require electric energy as a main energy source. However, the use of electric energy is often limited by space and/or weight requirements of the specific use case. Many conventional systems use electro-chemical batteries. Such batteries have been improved over the years to have higher energy densities, but current performance is approaching a theoretical maximum on the achievable energy density. Thus, there is a need to develop a battery with higher energy density than is achievable using conventional approaches.

### SUMMARY

An electric energy storage device includes a battery cell and an electronic device. The energy storage device can store an electric energy and also release the stored energy like a battery. The battery cell includes two electrodes and a multilayer structure with many (e.g., millions of) quantum layers. The multilayer structure includes a superlattice structure having minibands. The superlattice structure may be fabricated by stacking a layer of quantum well and a layer of quantum barrier alternatively. The thickness of the quantum layers may be in the nanometer range.

In various embodiments, the electro-chemical reaction principle is not employed in the function of the device, but rather the physical principle is used. The supplied energy is stored as a Coulomb potential energy in the superlattice structure by producing an electric dipole system and stabilizing the physical and electrical structure. The stored electrostatic energy density is boosted with increasing an electric charge density in the structure.

The stored energy may be released by bombarding the electrical structure of the cell with a trigger pulse power for discharge. The released electronic charges get excited to the conduction band and the electric currents are generated.

This novel working principle of charging and discharging mechanism makes the specific energy density of the battery viable to be increased drastically relative to conventional, electro-chemical approaches.

### BRIEF DESCRIPTION OF THE DRAWINGS

FIG. 1 illustrates a multi-layer structure of a quantum dipole cell, according to one embodiment.

FIG. 2 illustrates a super-lattice structure of a quantum dipole cell, according to one embodiment.

FIGS. 3A-D illustrate various dipole structures that may be formed to store energy within the quantum dipole cell, according to various embodiments.

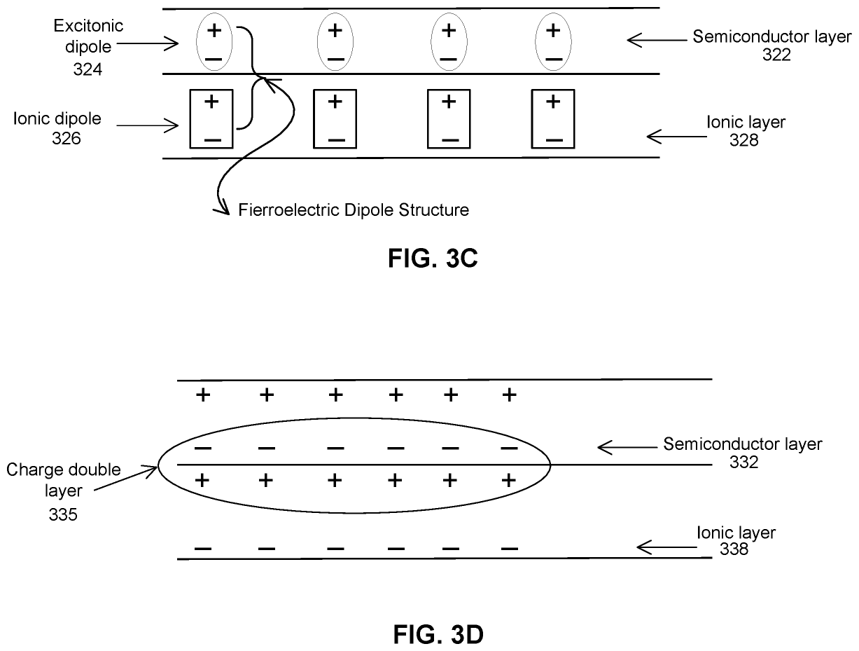

FIG. 4 is a conceptual illustration of a discharge process for a quantum dipole cell, according to one embodiment.

### DETAILED DESCRIPTION

The figures and the following description describe certain embodiments by way of illustration only. One skilled in the art will readily recognize from the following description that alternative embodiments of the structures and methods may be employed without departing from the principles described.

### Overview

In one embodiment, a quantum dipole battery includes a positive electrode, a negative electrode, and a multilayer structure. The multilayer structure is disposed between the positive electrode and the negative electrode and defines a quantum superlattice that includes a plurality (e.g., millions) of bilayers. Each bilayer includes a quantum well layer and a quantum barrier layer. The quantum well layer is separated from and coupled to an adjacent quantum well layer by the quantum barrier layer. The multilayer structure defines a microcavity including quantum well layers and quantum barrier layers, each having a thickness of nanometer scale. Incident quantum electric dipolar waves are reflected and confined in the microcavity of the multilayer structure, with the microcavity providing confinement of excitonic and ionic dipolar waves (E.I.D. waves).

Excitons and indirect excitons are created due to the coupling between the adjacent quantum wells or a Rabi oscillation mechanism or in the quantum barrier layer or its surfaces which are sandwiched by the quantum well layers. Adjacent quantum wells and barriers Are coupled together with quantum E.I.D. waves in the quantum superlattice through a long range phase correlation. Electronic charges are transported by a phonon-assisted quantum tunneling or a hopping mechanism through the quantum barrier layers, with the coupling of adjacent quantum well layers and quantum barrier layers resulting in a dipole-dipole interaction between excitonic dipoles and ionic dipoles with confinement of quantum dipoles in an area of quantum wells and quantum barriers in the microcavity. The multilayer structure has a pseudo-one-dimensional structure in a longitudinal direction to two-dimensional horizontal layers which are stacked in that direction, and the E.I.D. waves can be reflected in the longitudinal direction and confined in the microcavity.

In some embodiments, the multilayer structure is a quantum superlattice structure which includes a Distributed Bragg Reflector (DRB) or a reflector layer made from one or more insulator materials. The thickness of the reflector layer is in the micrometer range. The quantum superlattice structure may also include a second DRB or a second reflector layer made from one or more insulator materials. The DRB or reflector layer and the second DRB or second reflector layer sandwich the plurality of bilayers.

The quantum well layers can be nanosized layers of a conductor, a semimetal, a semiconductor, or a quantum dot material. The quantum barrier layers can be nanosized layers of an ionic material, a polar molecule, a dielectric material, or an electrically polarizable material, which are adapted to become polarized in response to an applied field.

The positive electrode and the negative electrode can be configured to be attached to corresponding metal sheets. The corresponding metal sheets can be coated with at least one of activated carbon powder, graphite, or graphene.

The multilayer structure may be manufactured by utilizing molecular beam epitaxy, chemical vapor deposition, a 3D printing technique, or a slurry mixing technique on a bulk scale to produce the multilayered structure. The battery cell may be fabricated by means of a slurry mixing technique with an activated carbon powder, a binder, and active materials. The activated carbon powder can be a micro-sized porous material which has graphite layers. The activated carbon powder may have a large surface area due to a high degree of porosity. The ionic layers may be made of active materials and binders which are adsorbed into surfaces of the carbon to form the nanosized layer.

Each bilayer on the multilayer structure may include a semiconductor layer and an ionic layer such that the stack of bilayers is a superlattice. The semiconductor layers are quantum wells of the superlattice and the superlattice structure can be fabricated by stacking layers alternatively from different materials with a period. The quantum well layer of the bilayer may be a nanosized layer made of a conductor, semimetal, direct transition semiconductor, indirect transition semiconductor, or quantum dot material, such as activated carbon, graphite, graphene, or nanotubes.

The quantum barrier layer may be a thin layer made of ionic molecules, polar molecules, dielectric materials, electrically polarizable materials, or mineral materials. Example polarizable materials include electronic polarization, ionic polarization, dipolar molecule polarization, or space charge polarization materials. Example ionic polarization materials include magnesium sulfate, sodium bicarbonate, sodium carbonate, cesium bicarbonate, cesium carbonate, lithium carbonate, potassium carbonate, rubidium carbonate, ionomers (ionic polymer), an alum, or a mineral.

The magnitude of a thickness of the quantum well layers may be close to a de Broglie wavelength such that a corresponding electronic wave function is represented by a quantum harmonic wavefunction. As the magnitude of thickness is in the nanometer scale, the eigen energy levels become quantized and discrete and are size dependent.

The superlattice can be a periodic heterostructure comprised of alternating different types of layers, which are semiconductor layers and ionic layers. The semiconductor layer is a quantum well and the ionic layer is a barrier of a superlattice. The quantum well layer is made of graphite and graphene, and the ionic layer is made of at least one of sodium carbonate, sodium bicarbonate, or magnesium sulfate(Epsomite). The thickness of the quantum well and barrier layers is nanosized in the superlattice structure, so that the superlattice provides three forms of electron transportation: a miniband conduction, Wannier-Stark hopping, and phonon-assisted tunneling, providing a nonlinear behavior, a negative differential conductivity, and a superlattice current oscillation, respectively.

The multilayer structure can be a quantum superlattice which is composed of millions of quantum wells of superlattice minibands and quantum barriers of coherent optical phonons such that the minibands are originated from a periodicity of the superlattice and nanosized thickness of the barriers and wavefunctions of electrons and holes are no longer localized in a certain quantum well, but exist all over the superlattice structure, but wavefunctions of the coherent optical phonons are localized in a certain barrier layer.

Exciton creation in the quantum wells can be induced by phonon-assisted tunneling and hopping conduction crossing the barrier layer with an external field and excitation of a valence electron leaving a hole behind, which are attractive by Coulomb force, the mechanism being strengthened by miniband formation, thermal stimulation, and/or nonadiabatic transition of a two-level system in the quantum well, the transition being induced by coherent polarized optical phonon wavefunctions, and Rabi oscillation. Excitonic transition dipoles and phonon transition dipoles may be created in the superlattice with an applied electric field, and characteristics of the excitonic transition dipoles of the quantum wells are uniquely determined by specific properties of the superlattice, the transition dipole characteristic of the polarized wavefunctions of optical phonons being a unique property of the quantum barriers in the superlattice, which is induced by the applied electric field.

A charging process for the battery involves applying an external power through the electrodes such that supplied energy from an external power source is transferred to the quantum superlattice in the multilayer structure by means of hopping/or tunneling conduction, a nonadiabatic excitonic dipole, and/or a phonon dipole creation mechanism, and a propagation of excitonic and ionic dipolar wavefunctions. The physical mechanism transferring the electric energy from the power source to the superlattice includes employing a polaronic/Wannier-Stark hopping conduction mechanism, a quantum tunneling, a nonadiabatic transition, and/or Rabi oscillation in the superlattice structure. The electron hopping through the ionic barrier layer is assisted by an optical phonon of a coherent state and a thermal stimulation.

Minibands of the quantum well in the superlattice structure are a two-level system as long as the excitonic dipole creation and annihilation are related, which are two energy eigenstates of the two-level system. The two-level system can be decoupled from other degrees of freedom of the system in the quantum wells. The two-level system can be a pair of conduction and valence bands which is separated from other energy bands in this specific kind of quantum superlattice so that the two-level system is feasible energetically in creation of the excitonic dipoles in the quantum wells with an applied external electric field.

Valence electrons can jump to the conduction band by a nonadiabatic transition with the applied field to form the excitonic states in the two-level system by means of Rabi oscillation mechanism. Excitonic state formation in the quantum wells and superlattice may occur by a hopping conduction mechanism through the barrier layer that is strengthened by a thermal stimulation and the polarized optical phonon. Excitonic excitation and its propagation in the quantum superlattice structure may be processed by a polaronic hopping conduction and a phonon assisted quantum tunnelling. The excitonic wavefunctions can propagate through potential barriers from a quantum well to the next adjacent quantum well.

A coherent dipolar wavefunction in the barrier layer may be a displaced vibration of the optical phonon, and an excited phonon system turns, by the applied field, eventually into a dipolar phonon system of coherent state in the barrier layers. The oscillatory evolutions of the excited and polarized ionic phonons in the barrier layers can be represented as wavefunctions of quantum physics, preserving specific phase and amplitude, which is a coherent state. Transition dipole systems of coherent wavefunctions may continue to propagate over the superlattice structure as energy is supplied to the system, and electronic states of two-level systems interacting with the applied electric field can be excited to produce excitonic dipoles in the quantum wells of the superlattice. Transition dipole moments can take supplied electric energy by a nonadiabatic process.

Excitonic dipolar oscillations are vibrations of a nucleus which are due to nonadiabatic electronic transitions, which promote a dipole wavefunction of coherent state in the quantum well, and a quantum effect of the superlattice can be a standing wave formation or traveling waves in the quantum wells and the quantum barriers. The wavefunctions of localized excitonic dipole moments may allow a basis for expansion of dipole states, which are collective vibrations of coherent states in the superlattice.

Nonadiabatic coupling can drive quantum transitions between states of a two-level system, leading to collective vibrations of an excitonic system in the quantum well. Oscillatory evolutions of the excited electrons and the holes in the quantum wells are represented as quantum coherent wavefunctions, preserving specific phase and amplitude, which is a coherent state, where eigen-modes and energy levels are quantized and size-dependent.

Phonon wavefunctions of a polarized and displaced vibration can be excited by an external field and are optical phonons of a coherent state. Eigen modes of the phonon are quantized in the barrier layer, which is a coherent state of a displaced harmonic oscillation, and quantum barrier layers of coherent states can act as microcavities that cause confinement of the optical phonon of longitudinal mode. Confinement of coherent excitonic dipoles in the quantum well layer and a proximate location, and collective polarization ordering of the coherent optical phonon dipoles of the barrier layer, make a quantum dipole-dipole interaction viable, and specific quantum superlattice structures can aid in inducing coupling of coherent quantum dipoles.

Collective dipole fields of coherent optical phonons of a longitudinal mode in the barrier layer can be coupled to transition dipoles of excitonic vibrations of the longitudinal mode in a two-level system of the quantum wells. Transition dipoles of quantum wells and transition dipoles of barriers can be coupled via quantum dipole-dipole interactions. Quantum dipole-dipole interaction between coherent excitonic wavefunctions and coherent optical phonons of longitudinal modes may occur in the heterostructures of the superlattice of the microcavity. This interaction induces a new coupled state of exciton and phonon that is metastable.

Stable electric nano-structures may be formed in the superlattice of the multilayer structure through a structural phase transition which is caused by an excitonic-ionic wavefunction of a boson bound state in the microcavity accompanying a spontaneous structural change. The spontaneous structural change may be one of a Mott-insulator or Peierls or phase transition of an electric charge system by activation of the polaronic interactions. The stable electric nano-structures may include at least one of a ferroelectric structure, an antiferroelectric structure, a surface exciton charge double layer structure, or an electric charge double layer structure on a boundary between the quantum well and the barrier. The supplied energy may be stored as an electrostatic potential energy in the nanostructures when the battery is charged.

A transition probability amplitude of energy state in a two-level system may oscillate with a Rabi frequency Ω which is proportional to an amplitude of the applied field such that electronic charges of the electric dipole systems are decoupled from the ionic dipole systems and excited to the conduction bands when a high electric field E and high power of a DC pulse or an AC are applied as a trigger power for discharge. Charge carriers may be released from the bound states and excited to conduction bands by the external trigger power and generate voltaic power with an oscillating electric field or pulse electric field in the superlattice. Voltaic power appears on the electrodes when the battery cell is activated for discharge by the trigger power, where the trigger power is a DC pulse power of higher voltage and fast rise time. A width of the pulse may be in a range of nanoseconds. The pulse may be applied to the battery cell through the negative and positive electrodes for discharge, where the released power from the battery cell is harvested and fed back to the input process at a feedback device.

Oscillating power or pulse shape power released from the activated battery cell may be due to an applied pulse and a collectively oscillating ionic dipole field and intrinsic properties of the superlattice. The released power may be rectified to DC output power and harvested. A small portion of harvested energy may be fed back for the trigger pulse generation through a feedback device and the remaining harvested energy used for other works.

### Example Electric Energy Storage Device

A new kind of battery cell employs a novel physical mechanism in contrast to the electro-chemical mechanism of a conventional batteries. In one embodiment, the battery cell is comprised of a multilayer structure and two electrodes, where the multilayer structure is a quantum superlattice. The battery cell may be fabricated with the superlattice structure by stacking them to form a multilayer structure, where the electrodes are attached to both surfaces of the multilayer structure to form a body of the cell. The battery cell has a positive electrode and a negative electrode, where an external power is applied to the electrodes of the cell in the process of charge and discharge. The superlattice functions as a Distributed Bragg Reflector (DBR) that reflects incident quantum electric dipolar waves. Alternatively, the incident quantum electric dipolar waves may be reflected by a reflector layer (e.g., a layer of GaAs—AlAs) having a thickness in the micrometer range).

In one embodiment, DC power is applied to the electrodes to make the electrons and the optical phonons excited and the supplied electric energy is transferred to the electric system in the multilayer structure. The energy transferred to the electronic system produces excitons in the superlattices structure and the polarized optical phonons in the barrier layers. The transition excitons of the quantum well are created by the interaction between the two-level system of the quantum well and the applied field. The coherent excitons and the coherent optical phonons are coupled through the quantum dipole-dipole interaction between the excitons and the optical phonons to create a new kind of the exciton-phonon state. The coupled state of the exciton and the optical phonon goes through a phase transition to an ordered static structure of electric charges or ferroelectric or anti-ferroelectric structure which is more stable than the dynamic coupling state. In this process, the electric energy supplied by the power source is stored in the battery cell.

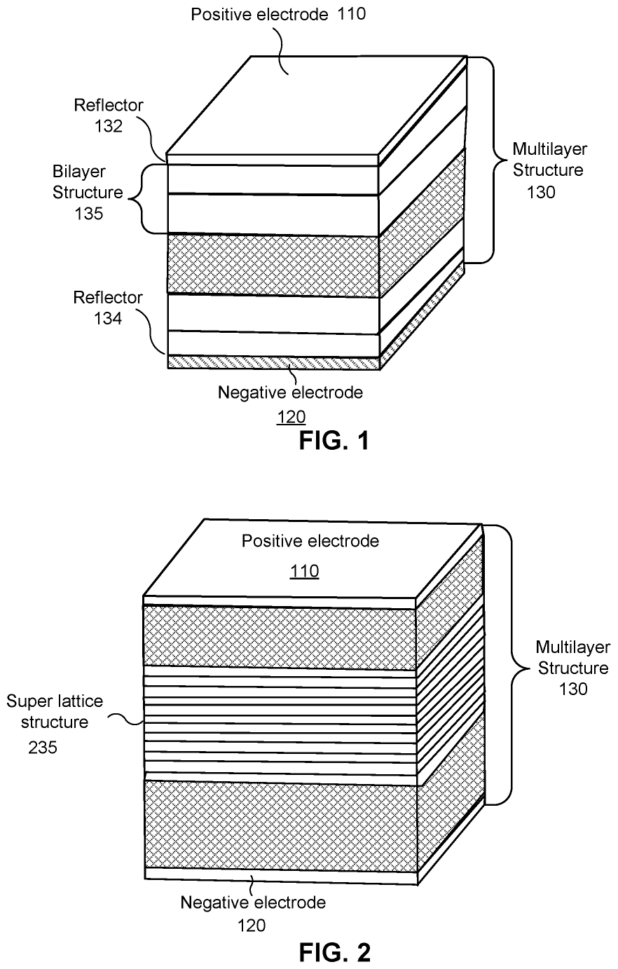

FIG. 1 illustrates a multi-layer structure of a quantum dipole cell, according to one embodiment. The quantum dipole cell has a positive electrode 110 on one side and a negative electrode 120 on the opposite side. Between the electrodes is a multilayer structure 130 made of many bilayer structures 135.

In various embodiments, the bilayer structures 135 each include a quantum well layer and a quantum barrier layer. The bilayer structures 135 are stacked to form the multilayer structure 130 such that the multilayer structure includes stacked layers that alternate between quantum well layers and quantum barrier layers. In some embodiments, the properties of the multilayer structure 130 (e.g., a periodicity of layers) results in the multilayer structure 130 acting as a DBR for incident quantum electric dipolar waves. For example, a DBR or other reflector 132, 134 may be positioned at the interface between a quantum well layer and a quantum barrier layer which is faced with the outer surface of activated carbon particle(s). Thus, the superlattice structure is sandwiched by the two DBRs or reflector layers 132, 134.

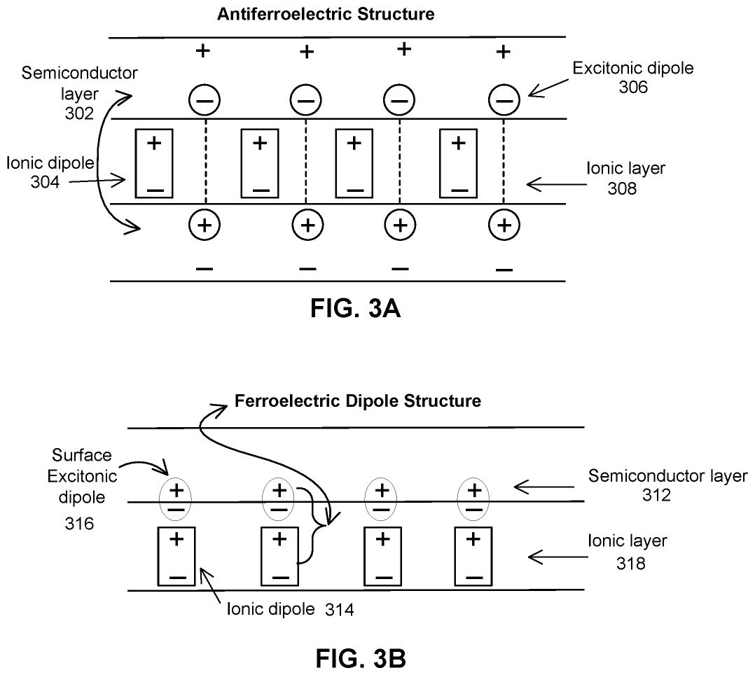

FIG. 2 illustrates that a multilayer structure 130 can form a quantum superlattice 235. The quantum superlattice 235 includes millions of bilayers 135, where transition excitons are produced in the quantum well layers and optical phonons are polarized in the quantum barrier layers by externally applied power. The multilayer structure 130 has a pseudo-one-dimensional structure in the vertical direction to the two-dimensional thin layers which are stacked along the vertical direction. An external field is applied in the vertical direction to the thin layers which are stacked in that direction. The charge carriers transport in the one-dimensional direction longitudinal to the horizontal layers in the multilayer structure 130, where the electronic energy states are quantized.

The dipole moments of the excitonic and optical phonon wavefunction of a coherent state are aligned in the one-dimensional vertical direction perpendicular to the horizontal layers. The coupling between the excitonic system of the quantum wells and the ionic systems of the quantum barriers occurs by the quantum dipole-dipole interaction which is attractive and sensitive to the direction. The transportation of the charge carriers is hindered by the coupling, which leads to storing the energy.

In one embodiment, millions of bilayers of heterostructures 135 may be closely stacked to form a multilayer structure 130 which has a pseudo-one-dimensional structure in the vertical direction to the layers. The coherent excitonic dipoles and the polarized coherent phonons are arranged along the one-dimensional vertical direction with the applied external field which is in the same one-dimensional direction as a transportation direction of the charge carrier. The coherent phenomena of the dipole states strengthen the coupling leading to a phase transition of the system to a more stable state in the bilayer heterostructure 135. The multilayer structure 130 may be fabricated by stacking the bilayer heterostructures 135 one by one to form a body of a battery cell. The multilayer structure 130 may be composed of quantum superlattices 235 of many (e.g., millions of) the quantum well layers and quantum barrier layers.

In one embodiment, the bilayer heterostructure 135 of the battery cell is composed of a thin nano-sized layer of quantum well and a thin nano-sized layer of quantum barrier, where the two layers are attached closely to form a thin bilayer structure. The quantum well layer of the bilayer 135 may be a thin layer of a conductor, a semimetal, a direct transition semiconductor, an indirect transition semiconductor, or a quantum dot material. The quantum barrier layer of the bilayer 135 may be a thin layer of an ionic molecule, a polar molecule, a dielectric material, or an electrically polarizable material, where the polarizable materials have at least one of an electric polarization, an ionic polarization, a molecular polarization, or a space charge polarization.

The nano-sized thickness of the quantum well layer enables the electrons and holes in the quantum wells to behave like a matter wave of which eigen-modes are quantized. The magnitude of the thickness of the quantum well layers may be close to de Broglie wavelength of the electronic wave function (e.g., within 5%), and a quantum confinement is considered in the quantum wells. If the magnitude of thickness of the quantum well layers is in the nanometer scale, the eigen energy levels become quantized and discrete, and are size dependent. A quantum well of the bilayer 135 also confines energy levels in one dimension in the vertical direction to the layer.

The quantum heterostructures may be fabricated using 3-D printing, molecular beam epitaxy, and/or molecular chemical deposition. In one embodiment, a thin layer of one or more quantum dot materials may be made by coating the whole surface of a conductor layer with the quantum dot materials.

The confinement of the electronic state in the quantum well layer and the proximate location of the optical phonons of the barrier layer strengthens a coupling between the two states. The dipole-dipole interaction between the coherent excitonic dipole wavefunction and the coherent optical phonon of longitudinal mode occurs in the bilayer 135 of the superlattice 235 to form a coupled state of exciton and optical phonon. The Hamiltonian of the coupled state can be diagonalized and the electronic system of the coupled state makes a transition to a stable state. The electronic dipole system also becomes stable by forming an ordered state of the electric charges and storing the supplied electric energy. The hopping electron conduction in the superlattice 235 structure is hindered by forming the rigid electric nano-structure which is produced by the supplied electric energy.

A band gap in a semiconductor is an energy range where no electron states between the conduction band and the valence band can exist due to the splitting of energy states as the atoms get closer. The electrical conductivity of a semiconductor is governed by excited electrons that jump from the valence band to the conduction band by a thermal stimulation. The electrons in conduction band and the holes in the valences band act as charge carriers when an electric field is applied by increasing their kinetic energy. In one embodiment, the quantum wells of the superlattice 235 are made of conductor or semiconductor materials. The quantum superlattice 235 of the multilayer structure 130 can include millions of bilayer heterostructures 135, where the bilayer heterostructure each include a nano-sized quantum well layer and a nano-sized quantum barrier layer, where millions of the bilayer heterostructures 135 are closely stacked one by one to form a multilayer heterostructure 130. The wavefunctions of the electrons and the holes are no longer localized in a certain quantum well, but they exist all over the superlattice structure 235, similar to a Bloch state. The thickness of the layers of the quantum wells and the quantum barriers in the superlattice structure 235 is in the nanometer range, where the electronic band structure in the quantum wells is dependent of the nano-sized thickness of the layers of the barriers and quantum wells.

A miniband formation in the quantum well depends upon a width of the quantum barrier and the quantum well. The electronic energy-states among the adjacent quantum wells are coupled together leading a formation of minibands in the quantum wells. The coupling causes a splitting of the quantized energy levels of quantum wells leading miniband formation. The miniband formation of the quantum well causes increasing a probability of hopping conduction and a quantum tunneling of the charge carriers from quantum well to the adjacent quantum well through the quantum barrier.

The quantum superlattice 235 splits energy states of electron in the quantum wells and the density of the bands are increased, so a valence electron can be excited to the conduction band leaving a hole in the valence state. The miniband in the quantum superlattice is closely related the width of the layers of heterostructure, which is in the range of nanometer scale. The thickness of the thin layer and the periodicity of the superlattice 235 drastically changes the band structures of the quantum superlattice.

The miniband formation of the quantum well depends upon the width of the quantum well and the barrier layer. If those widths are close to a nanometer scale, the bands are split, and the density of the bands increases. An increase of the available bands in the quantum wells increases as well hopping probability of the electrons passing through the barriers. The electron of the valance band in the quantum well can be excited and jump to a conduction band with the applied electric field leaving a hole in the valance band, and an exciton is created in the superlattice 235. The electrons and the holes of the excitons form dipole bound states by the Coulomb interaction. The exciton creation is induced by the mechanism of the hopping conduction and the excitation of electron to the conduction band, which is strengthened by the miniband formation in the superlattice structure 235.

The coherent and polarized electronic dipole states are created in the superlattice 235 in the direction of the applied field, which is vertical to the layers. These polarization characteristics are due to the vertically mixed and coupled electronic states among the quantum wells of the superlattice 235. A charge carrier of an electron transports in the vertical direction to the quantum well layer by a hopping conduction through the barriers leaving the hole in the other quantum well layer in the superlattice structure 235.

The excitonic dipole oscillations of the vibration of the nucleus which is due to nonadiabatic electronic transition, which promotes a dipole wave function of longitudinal mode, which is a coherent quantum oscillation. The excitons of the quantum well layer and the polarized optical phonons of the barrier layer are coupled by a quantum dipole-dipole interaction mechanism. This specific kind of quantum superlattice structure 235 plays a role of producing the excitons. The quantum barrier is sandwiched between the quantum wells. The thickness of the barriers is nanometer sized, so the polarized state of the optical phonon is a coherent state.

The polarized optical phonons in the coherent states interact with the excitonic dipoles. The stable electric structures are formed by the phase transition. In various embodiments, the energy supplied to the system is stored in a form of charge double layer or ferroelectric or anti-ferroelectric structure. A thickness of the quantum well layers and the quantum barrier layers are nanometer scale to form a quantum dipole system of excitons and ions, so that interaction between excitonic dipoles and ionic dipoles occur in the bilayer structure 135, where the quantum superlattice 235 is a multilayer structure which is comprised of millions of thin bilayer heterostructures of nanometer scale. A thickness of the quantum well layers and the quantum barrier layers may be nanometer scale to form a quantum dipole system of excitons and ions, so that interaction between excitonic dipoles and dipoles of optical phonon occur in the bilayer structure. The bilayer of the heterostructure 135 can be made of the thin layer of the quantum well and the thin layer of quantum barriers whose thicknesses are nanosized. The multilayer structure may be fabricated by stacking closely the bilayers of the heterostructures to form a quantum superlattice 235.

The cell may include a positive electrode 110 and a negative electrode 120 that are made of conductor or semiconductor materials. The active materials and/or graphite may be coated to the surface of the metal sheet.

### Excitonic Dipole Creation Mechanism and Excitonic Resonance

The excitonic dipoles can be created in the quantum wells by the hopping mechanism of electrons through the barrier layers and the nonadiabatic transition interaction between the two-level systems of the quantum wells and the optical phonons of the barriers with the applied electric field. A real exciton is a two-particle correlation by Coulomb interaction between an electron and a hole. The excitonic resonances are determined by all transition probabilities of the transition dipole moments between the two states and are not perturbed by presence of real excitons.

A quantum system of two independent quantum states is a two-level system. The miniband of the quantum well in the superlattice structure can be treated as a two-level system as long as the exciton creation and destruction considered, which is related to two eigenstates of the system. The two-level systems are decoupled from the other degrees of freedom of the system. In one embodiment, a two-level system includes a pair of bands which is separated from higher energy bands in the quantum superlattice so that the two-level system is feasible energetically. The coupled quantum wells are separated by a barrier from each adjacent coupled quantum wells in the superlattice. The quantum well is made of semiconductor, conductor materials and/or quantum dots materials. The valance band electron is excited leaving a hole in the valance band and moves to the higher energy level in the conduction band. The Coulomb interaction between the hole and electron causes them to be of a bound state in a two-level system. The excitonic dipole system is formed in the layer of the quantum well.

A miniband in the quantum superlattice is closely related to the thickness of the layers of heterostructure, which is in the range of nanometer scale. The thickness of the thin layer and the periodicity of the superlattice drastically changes the band structures of the quantum wells. The quantum superlattice splits energy states of electron in the quantum wells and the density of the bands are increased, so a valence electron is able to get excited to the conduction band leaving a hole in the valence state, which is a two-level system.

The electronic charges can be excited to the higher level of the two-level system by a hopping conduction mechanism through the barrier layer where the electrons are accelerated by the applied field, which is strengthened by a thermal stimulation, and the optical phonon, which is a polaronic conduction. A charge carrier transportation can also strengthen an exciton creation in a quantum well by a hopping of an electron from a quantum well layer to the next adjacent quantum well layer. The electron conduction by hopping to the nearest quantum well layer through the ionic barrier layer is assisted by the optical phonon of a coherent state. The polaronic hopping process which is a nearest-neighbor hopping and a variable range hopping, and quantum tunneling contributes a creation of excitons in the quantum well.

### Example Superlattice Structures

A superlattice is a periodic heterostructure made of alternating quantum well layers and quantum barrier layers. The quantum well layers are layers that include a conductor, a semimetal, a semiconductor, or a quantum dot material. The quantum barrier layers are layers that include an ionic material, a polar molecule, a dielectric material, or an electrically polarizable material. The quantum barrier layers become polarized in response to an applied field. In one embodiment, the thickness of the quantum well and barrier layers is nanosized in the superlattice structure, so that the superlattice can have the three approaches of transportation, which are a miniband conduction, Wannier-Stark hopping, and sequential tunneling. These provide a nonlinear behavior, a negative differential conductivity, and a superlattice current oscillation.

The periodic layer structure of a superlattice implies that the electronic states of the quantum wells form delocalized minibands. The thickness of the thin layer and the periodicity of the superlattice drastically changes the band structures of the quantum superlattice. A miniband formation in the quantum well depends upon a layer thickness of the quantum barrier and the quantum well, which is in the range of nanometer scale. The electronic energy-states among the adjacent quantum wells are coupled together leading a formation of minibands in the quantum wells. The coupling causes a splitting of the quantized energy levels of quantum wells leading miniband formation. The barriers are thin enough that the electronic wavefunctions of adjacent quantum wells are coupled to form minibands.

The bandgaps of the minibands become discrete as the thickness of the quantum wells becomes nanosized. If an electric field is applied, the combination of the electric field, the periodicity of the layers, the nanosized thickness of the layers causes a superlattice current oscillation and a Wannier-Stark hopping.

### Collective Vibration of Polarized Dipole System in Coherent State

A dipole has a potential energy by Coulomb interaction between the positive and negative charges. The harmonic approximation may be employed to obtain a model of the collective dipole systems in a superlattice structure. The potential V(q) between the positive and negative charges which oscillate can be expanded in a series expansion at the equilibrium position, q=0.

$$V ( q ) \approx V ( 0 ) + \frac{\partial V}{\partial q} q + \frac{1}{2} \frac{{\partial }^{2} V}{\partial {q}^{2}} {q}^{2} +$$

where the potential is harmonic in the limit of small displacement, the potential is:

$$V ( q ) = \frac{1}{2} \frac{{\partial }^{2} V}{\partial {q}^{2}} {q}^{2} = \frac{1}{2} {kq}^{2}$$

where

$$k = \frac{{\partial }^{2} V}{\partial {q}^{2}} ,$$

is a force constant.

The equation of motion is:

$${\ddot{p}}_{l} + {ω}_{l}^{2} {p}_{l} = 0$$

where pₗ is a polarization field and ωₗ² is a frequency of longitudinal mode.

In quantum physics, Schrödinger equation using this harmonic potential to calculate the wave functions and eigen-energies of the vibrations is:

$$- \frac{{ℏ}^{2}}{2 μ} \frac{{\partial }^{2} ϕ}{\partial {q}^{2}} + \frac{1}{2} {kq}^{2} ϕ = E ϕ$$

where μ is a reduced mass of the dipole.

The wave-packets of these wavefunctions depending on 2+1 dimensional vibrational degrees of freedom adopt a standing wave pattern of longitudinal mode in the nanosized layer structures of the quantum well following the particle in a box model. The eigen values of the wavefunction are quantized.

$${E}_{n} = 〈 {ϕ}_{n} \vert ( {a}^{†} a + \frac{1}{2} ) \vert {ϕ}_{n} 〉 ℏω = ( n + \frac{1}{2} ) ℏω$$

where n=0, 1, 2, 3 . . . a^{†} and at and a are a step-up and a step-down operator respectively.

A transition dipole moment is associated with a transition between an initial state, ϕₙ; and a final state, ϕₘ, which is a dynamics of the energy transfer. In the presence of an electric field, the vibration of the excitonic dipoles in the quantum wells follow a standing wave pattern which is a coherent wavefunction of a harmonic oscillator. The coherent dipolar field in the quantum well is a vibration of excitonic dipoles, which is quantized by the boundary conditions of the quantum well.

The energy states of the electrons in the one-dimensional direction perpendicular to the horizontal layers are quantized. In harmonic oscillator potential, a momentum and a position are represented as operators of quantum physics:

$$\vec{r} = \sqrt{\frac{ℏ}{2 m ω}} ( {a}^{†} + a )$$

$$\vec{p} = \sqrt{\frac{ℏ m ω}{2}} ( {a}^{†} - a )$$

The transition dipole moment is:

$$\vec{d} = e 〈 {φ}_{a} \vert \vec{r} \vert {φ}_{b} 〉 = e \sqrt{\frac{ℏ}{2 m ω}} 〈 {φ}_{a} \vert ( {a}^{†} + a ) \vert {φ}_{b} 〉$$

The optical phonon of the quantum barrier layer in the superlattice structure is a polarized wavefunction with an applied electric field. This polarization with oscillation is called a polarization field. The displaced oscillation in the direction of the field is an oscillation of longitudinal mode. The optical phonon of horizontal mode is a collective oscillation of the ions in the two-dimensional layer.

For the polarization of oscillation of the optical field in the uniform electric field,

$${\ddot{p}}_{i} + {ω}_{L}^{2} {p}_{i} = 0$$

where ω_{L} is a longitudinal frequency.

The ionic wavefunction of optical phonon and displaced vibration in the barrier layer is excited by the external field, which is an optical phonon of longitudinal mode. The wavefunction of the phonon is bounded by the boundaries of the barrier layer. The eigen modes of the phonon is quantized, which is like a particle in a box, which is an optical phonon of longitudinal mode of a coherent state.

$${E}_{n} = ( n + \frac{1}{2} ) ℏω$$

The longitudinal mode of the polarization phonon interacts the longitudinal mode of the excitonic dipole vibration. An optical phonon can be polarized and excited by an applied external field. In one embodiment, the quantum barrier is a thin layer of ionic or dielectric materials, polar molecules, or polarizable materials, and is a boundary of a quantum well. The quantum barrier is a thin layer in which an optical phonon is excited and polarized by the external field. A dipole wave function in the superlattice is a complete set of orthogonal functions like the Wannier functions. The localized dipole functions allow a basis for the expansion of dipole states.

The excitons in the quantum wells are created by absorbing electric energy from the applied electric field. The energy is supplied from the external sources and transferred to the electronic system of the superlattice structure. In this process, the excitonic dipole systems in the quantum wells are created by the supplied energy.

In some embodiments, a hopping electron which is excited and stimulated by the applied electric field transports, with assistance by the collective optical phonon of the barrier layer, to the adjacent quantum well for tunneling through the quantum barrier. A two-level system of the quantum wells interacts with the applied coherent electric field and results in an oscillation of the probability of the electronic states of the two-level system. Eventually two systems of an electronic wavefunction of coherent state and an ionic wavefunction of coherent state are coupled to go to a phase transition. The provided electric energy is stored in the system by Coulomb static potential in an ordered state.

The excitons may be created in the quantum wells of the superlattice structure by the coupling between the two-level system in the quantum well and the applied electric field. But the solution of the transition probability of the two-level system is oscillatory in creation and annihilation representation. The vibration of the excitons is a coherent harmonic oscillation, inducing a coherent state of an excitonic dipole oscillation. An excitonic dipole wave function is a complete set of orthogonal functions like the Wannier functions. The localized excitonic dipole functions allow a basis for the expansion of dipole states in the superlattice structure. An excitonic dipole system aligned in one dimension with vibrating excitons forms a coherent collective vibration.

In one embodiment, a two-level electronic system interacting with the external electric field is stimulated to produce the excitonic dipoles in the quantum well of the superlattice. The transition dipole moments of the two-level systems of the quantum wells in the superlattice structure coupled with the electric field of the coherent state absorb an electric energy by nonadiabatic process from the applied electric field. The interaction potential is:

$$V ( t ) = - \hat{μ} \cdot \vec{E}$$

where \hat{μ} is a transition dipole moment of the two-level system and \vec{E} is the applied electric field and the field of the coherent optical phonon. The coherent dipole field of the optical phonon is coupled to the transition dipole moment of the two-level system. The transition of the electronic state from the lower level to the higher level is induced by the coupling and the excitonic transition dipoles that are created.

A physical mechanism transferring the electric energy from the applied electric field to the electronic system by creating excitons can employ Rabi oscillation theory. The electronic charges can be excited to the higher level of the two-level system by a hopping conduction mechanism through the barrier layer, which is strengthened by a thermal stimulation and the optical phonon. A charge carrier transportation also strengthens an exciton creation in a quantum well by a hopping of electron from a quantum well layer to the next adjacent quantum well layer. The electron conduction by hopping through the ionic barrier layer is assisted by the optical phonon of a coherent state. The applied electric energy by the external power is transferred to the electronic system through the process of the exciton creation in the quantum wells.

The one-dimensional ordering of the vibrating excitonic dipoles in the nanosized quantum well can be coherently matched with the boundary conditions of the quantum well. Thus, the excitonic dipole systems in the quantum well are in a coherent state of a harmonic oscillation due to the excitonic vibration of positive and negative charges.

A coupling of the excitonic dipole moments of a coherent state and the optical phonons of the coherent state is due to a dipole-dipole interaction. The interaction energy of H_{I} of a quantum system interacting with a time dependent coherent optical phonon field of longitudinal mode and the coherent excitonic wavefunction of longitudinal mode is given by:

$${H}_{I} = - {\vec{μ}}_{e} \cdot \vec{E} ( r , t )$$

where \vec{μ}ₑ is an excitonic dipole moment and \vec{E}(r,t) is an electric field of the phonon from the barrier layer. If a coherent phonon wavelength is long compared to system size of the dipoles, we can ignore \vec{r} dependence of \vec{E}(r,t) and assume that the system is in spatially uniform \vec{E}(t) oscillating in time.

The quantum dipole-dipole interaction term is:

$${H}_{I} = - γ {\vec{μ}}_{e} \cdot {\vec{μ}}_{p}$$

where γ is a constant and \vec{μ}ₚ is a transition dipole moment of phonon.

The interaction between the excitonic dipole and phonon dipole can be expressed as:

$$I = - {\sum }_{ij} γ ( {\hat{σ}}_{i}^{+} {\hat{σ}}_{j}^{-} + {\hat{σ}}_{i}^{-} {\hat{σ}}_{j}^{+} )$$

where γ is a constant and the operators \hat{σ}ᵢ⁺\hat{σ}ⱼ⁻ and \hat{σ}ᵢ⁺\hat{σ}ⱼ⁻ describe a creation of a transition dipole moment on a layer together with an annihilation of a transition dipole moment on the adjacent layer.

The coupling between the dipole moment of the coherent optical phonon and the excitonic dipole moment can lead to diagonalization of the Hamiltonian. The boson operators \hat{α}ₖ^{†}, \hat{α}ₖ and \hat{β}ₖ^{†}, \hat{β}ₖ of are creation and annihilation operators of the exciton and phonon of coherent state.

A displacement operator of a coherent state is:

$$\vert α 〉 = D ( α ) \vert 0 〉 = {e}^{α {\hat{a}}^{†} - {α}^{*} \hat{a}} \vert 0 〉$$

$$\vert α 〉 = {\hat{α}}_{k}^{†} \vert 0 〉 , \vert β 〉 = {\hat{β}}_{k}^{†} \vert 0 〉$$

The boson operators of coherent states satisfy the commutation relations:

$$[ {\hat{α}}_{k} , {\hat{α}}_{{k}^{′}}^{†} ] = {δ}_{{kk}^{′}} , [ {\hat{β}}_{k} , {\hat{β}}_{k}^{†} ] = {δ}_{{kk}^{′}}$$

The Hamiltonian of the system is:

$$H = {\sum }_{k} ( {E}_{k}^{e} {\hat{α}}_{{k}^{′}}^{†} {\hat{α}}_{k} + {E}_{k}^{p} {\hat{β}}_{k}^{†} {\hat{β}}_{k} ) + \frac{1}{2} I {\sum }_{k} {\hat{α}}_{{k}^{′}}^{†} {\hat{β}}_{k}^{†} {\hat{α}}_{k} {\hat{β}}_{k}$$

where Eₖ^{e} is an energy eigenvalue of the excitonic wavefunction, Eₖ^{p} is an energy eigenvalue of the phonon wavefunction, and I is a dipole-dipole interaction term.

The Hamiltonian can be diagonalized:

$$H = {\sum }_{k} ( {E}_{k}^{A} {A}_{k}^{†} {A}_{k} + {E}_{k}^{B} {B}_{k}^{†} {B}_{k} )$$

The ground states of the quasi-particles are the vacuum states where single quasi-dipole does not exist. The ground state with normalization is:

$$\vert G 〉 = {\prod }_{k} {\hat{α}}_{k} {\hat{β}}_{k} \vert α 〉 \vert β 〉$$

The ground state of the quasiparticles is a Bose Einstein condensate state.

The diagonalized Hamiltonian not only modifies the energy eigenvalues, Eₖ^{e} and Eₖ^{p}, but also superposes the operators. This superposition of two operators which is due to the coupling of the two wavefunctions leads more stability of the bound states which may be called an Excitonic and Ionic Dipolar wave (E.I.D. wave). This condensate state leads to a structural phase transition by activation of the Coulomb interactions between the electronic charges and ionic charges.

### Example Charge and Discharge Mechanism

In various embodiments, the charging process occurs by applying DC external power to the electrodes of the battery cell in the longitudinal direction of the electric field. The supplied energy from an external power source is transferred to the electronic system of the superlattice structure in the multilayer by a hopping conduction and a nonadiabatic exciton-creation mechanism of the two-level system in the quantum wells.

The excited electronic system turns eventually into a coherent excitonic dipole system ordered in the longitudinal direction to the horizontal layer surface. The excitonic dipole system is a coherent wavefunction of the electrons and the holes, propagating in the longitudinal direction. The coherent dipolar vibrational dynamic is due to the non-adiabatic transition of the two-level system which is stimulated by the applied electric field across the superlattice.

The non-adiabatic coupling drives quantum transitions between the two states of the two-level system, leading to a collective vibrational excitation and to the coupled excitonic electron-hole system in the quantum well. The oscillatory evolutions of the excited electrons and the holes in the quantum wells are represented as a wavefunctions, vibrating of the positive charges and the negative charges, preserving specific phase and amplitude, which is a coherent state of a harmonic oscillation.

As the thickness of the quantum well layers decrease and reach the nanoscale, the wavefunction of the particle is a matter wave of quantum physics, and the energy spectrum becomes quantized. As a result, the bandgaps of the quantum well become size-dependent by the boundary conditions. The energy eigen values are quantized. As the size of the barrier layers decrease, the adjacent quantum wells become close and they are coupled each other. Minibands are created in the quantum well due to this coupling.

The phonon wavefunction of a polarized and displaced vibration in the barrier layer arises by the external field, which is an optical phonon of longitudinal and transversal mode. The wavefunction of the phonon is bounded by the boundaries of the barrier layer. The eigen modes of the phonon is quantized, which is like a particle in a box, which is an optical phonon of longitudinal mode of a coherent state. The barrier layers for coherent state acting like a microcavity produces confinement of the optical phonon modes along the direction perpendicular to the horizontal layer.

In one embodiment, a coupling between the excitonic dipole wavefunction of the coherent state in the quantum wells and the optical phonon in the barrier layer is induced through a dipole-dipole interaction mechanism. The Hamiltonian including the coupling of the coherent dipole of longitudinal oscillation and the coherent optical phonon of longitudinal mode can be diagonalized, and the new combined wavefunction of the two bosons becomes a new particle. The paired wavefunction is a new kind of quantum boson. In this way the electrons and holes of the excitons are locally trapped and the charge carrier transportation is blocked.

An electronic and ionic polarization can cause ferroelectric or anti-ferroelectric effects as well as a structural phase transition by lining up the orientations of permanent dipoles along a particular direction. This is referred to as an order-disorder phase transition. The phase transition caused by ionic and excitonic polarizations in the dipolar system is a displacive or structural phase transition. In this nano structure, the transferred electric energy can be stored in a stable state.

In one embodiment, the dipole-dipole interaction is activated between the coherent excitonic dipoles and the coherent optical phonons when those are in the coherent states in proximate contact. The charge carrier transportation is blocked when it is dominated by the dipole-dipole interaction. Transferred energy from a DC power supply transits to electrostatic energy with the dipole system of the excitons and optical phonons which are created with the transferred energy.

In one embodiment, the Rabi mechanism is employed for discharge. The dynamical dipoles in the two-level system interact with the external applied trigger pulse \vec{E}. The transition dipoles can be described by a raising and lowering operator with pseudo-spin operators. The transition probability amplitude of the dipole in the system is:

$$〈 ϕ ( t ) \vert \hat{d} \vert ϕ ( t ) 〉 = 〈 ϕ ( t ) \vert ( P {\hat{σ}}^{+} - {P}^{*} {\hat{σ}}^{-} ) \vert ϕ ( t ) 〉 \approx Psin ( 2 Ω t )$$

$$〈 ϕ ( t ) \vert \hat{d} \vert ϕ ( t ) 〉 = 〈 ϕ ( t ) \vert ( P {\hat{σ}}^{+} - {P}^{*} {\hat{σ}}^{-} ) \vert ϕ ( t ) 〉 \approx Psin ( 2 Ω t )$$

$$H = - \vec{d} \cdot \vec{E} and Ω = \frac{P \vert \vec{E} \vert}{2 ℏ}$$

The transition probability amplitude of the dipole oscillates with a Rabi frequency Ω which is proportional to the amplitude of the applied field. Thus, the binding states of the electronic dipole systems are released from the ionic dipole systems when a trigger field \vec{E} is applied to the battery cell in a short period of time in the range of nano-seconds. The released charge carriers are excited to the conduction band and a voltaic power is generated with sinusoidal ionic dipole field. Thus, the battery cell is activated for discharge by the trigger power. The intrinsic electric field which is sinusoidal is generated due to the collective oscillation of the ionic dipole moments in the activated battery cell for discharge.

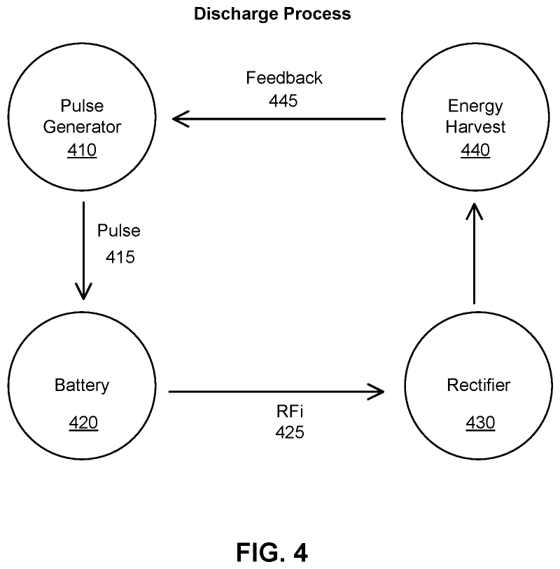

FIG. 4 illustrates one embodiment of the discharge process. In the embodiment shown in FIG. 4, a pulse generator 410 provides a pulse 415 to the battery 420. Due to the Rabi mechanism and Bloch oscillation, the pulse causes the battery 420 to release an alternating current 425 that is provided to a rectifier 430 that converts it into direct current. The direct current is provided to an energy harvester 440 which directs at least a portion of the power to the device being powered by the battery 420. The energy harvester 440 also provides feedback 445 to the pulse generator 410 to control the parameters of the next discharge pulse generated so that the energy stored in the battery 420 is released in a controlled manner that meets the needs of the specific use case.

### Additional Considerations

Any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment. Similarly, use of “a” or “an” preceding an element or component is done merely for convenience. This description should be understood to mean that one or more of the elements or components are present unless it is obvious that it is meant otherwise.

Where values are described as “approximate” or “substantially” (or their derivatives), such values should be construed as accurate +/−10% unless another meaning is apparent from the context. From example, “approximately ten” should be understood to mean “in a range from nine to eleven.”

The terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Upon reading this disclosure, those of skill in the art will appreciate still additional alternative structural and functional designs for a quantum dipole battery and corresponding charge/discharge mechanism. Thus, while particular embodiments and applications have been illustrated and described, it is to be understood that the described subject matter is not limited to the precise construction and components disclosed. The scope of protection should be limited only by any claims that may issue.

What is claimed is:

1. A quantum dipole battery comprising:
a positive electrode;
a negative electrode; and
a multilayer structure, disposed between the positive electrode and the negative electrode, the multilayer structure defining a quantum superlattice that comprises a plurality of bilayers, each bilayer including:
a quantum well layer; and
a quantum barrier layer, the quantum well layer being separated from and coupled to an adjacent quantum well layer by the quantum barrier layer,
wherein:
the multilayer structure defines a microcavity comprising quantum well layers and quantum barrier layers, each having a thickness of nanometer scale;
incident quantum electric dipolar waves are reflected and confined in the microcavity of the multilayer structure, the microcavity providing confinement of excitonic and ionic dipolar waves (E.I.D. waves);
excitons and indirect excitons are created due to the coupling between the adjacent quantum wells or a Rabi oscillation mechanism or in the quantum barrier layer or its surfaces which are sandwiched by the quantum well layers, adjacent quantum wells and barriers being coupled together with quantum E.I.D. waves in the quantum superlattice through a long range phase correlation, electronic charges being transported by a phonon-assisted quantum tunneling or a hopping mechanism through the quantum barrier layers;
the coupling of adjacent quantum well layers and quantum barrier layers results in a dipole-dipole interaction between excitonic dipoles and ionic dipoles with confinement of quantum dipoles in an area of quantum wells and quantum barriers in the microcavity; and
the multilayer structure has a pseudo-one-dimensional structure in a longitudinal direction to two-dimensional horizontal layers which are stacked in that direction, and the E.I.D. waves can be reflected in the longitudinal direction and confined in the microcavity.

2. The quantum dipole battery of claim 1, wherein the multilayer structure is a quantum superlattice structure which comprises a Distributed Bragg Reflector (DRB) or a reflector layer made from one or more insulator materials, a thickness of the reflector layer being in a micrometer range.

3. The quantum dipole battery of claim 2, wherein the quantum superlattice structure further comprises a second DRB or a second reflector layer made from one or more insulator materials, the DRB or reflector layer and the second DRB or second reflector layer sandwiching the plurality of bilayers.

4. The quantum dipole battery of claim 1, wherein the multilayer structure comprises millions of the bilayers.

5. The quantum dipole battery of claim 1, wherein the quantum well layers are nanosized layers comprising a conductor, a semimetal, a semiconductor, or a quantum dot material.

6. The quantum dipole battery of claim 1, wherein the quantum barrier layers are nanosized layers comprising an ionic material, a polar molecule, a dielectric material, or an electrically polarizable material, which are adapted to become polarized in response to an applied field.

7. The quantum dipole battery of claim 1, wherein the positive electrode and the negative electrode are configured to be attached to corresponding metal sheets, the corresponding metal sheets having been coated with at least one of activated carbon powder, graphite, or graphene.

8. The quantum dipole battery of claim 1, wherein the multilayer structure is manufactured by utilizing molecular beam epitaxy, chemical vapor deposition, 3D printing technique, or a slurry mixing technique on a bulk scale to produce the multilayered structure.

9. The quantum dipole battery of claim 1, wherein the battery cell is fabricated by means of a slurry mixing technique with an activated carbon powder, a binder, and active materials.

10. The quantum dipole battery of claim 9, wherein the activated carbon powder is a micro-sized porous material which has graphite layers, the activated carbon powder having a large surface area due to a high degree of porosity, and wherein ionic layers are made of active materials and binders which are adsorbed into surfaces of the carbon to form a nanosized layer.

11. The quantum dipole battery of claim 1, wherein the multilayer structure is comprised of millions of the bilayers, each bilayer being composed of a semiconductor layer and an ionic layer, wherein:
the stack of bilayers is a superlattice;
the semiconductor layer is a quantum well of the superlattice; and
the superlattice structure can be fabricated by stacking layers alternatively from different materials with a period.

12. The quantum dipole battery of claim 1, wherein the quantum well layer of the bilayer is a nanosized layer made of a conductor, semimetal, direct transition semiconductor, indirect transition semiconductor, or quantum dot material, and the quantum well layer is made of activated carbon, graphite, graphene, or nanotubes.

13. The quantum dipole battery of claim 1, wherein the quantum barrier layer is a thin layer made of ionic molecules, polar molecules, dielectric materials, electrically polarizable materials, or mineral materials, the polarizable materials including at least one of electronic polarization, ionic polarization, dipolar molecule polarization, or space charge polarization materials, and the ionic polarization materials including at least one of magnesium sulfate, sodium bicarbonate, sodium carbonate, cesium bicarbonate, cesium carbonate, lithium carbonate, potassium carbonate, rubidium carbonate, ionomers(ionic polymer), an alum, or a mineral.

14. The quantum dipole battery of claim 1, wherein a magnitude of a thickness of the quantum well layers is close to a de Broglie wavelength such that a corresponding electronic wave function is represented by a quantum harmonic wavefunction, and as the magnitude of thickness is in the nanometer scale, the eigen energy levels become quantized and discrete and are size dependent.

15. The quantum dipole battery of claim 1, wherein the superlattice is a periodic heterostructure comprised of alternating different types of layers, which are semiconductor layers and ionic layers, wherein:
the semiconductor layer is a quantum well and the ionic layer is a barrier of a superlattice;
the quantum well layer is made of graphite and graphene, and the ionic layer is made of at least one of sodium carbonate, sodium bicarbonate, or magnesium sulfate(Epsomite); and
a thickness of the quantum well and barrier layers is nanosized in the superlattice structure, so that the superlattice provides three forms of electron transportation: a miniband conduction, Wannier-Stark hopping, and phonon-assisted tunneling, providing a nonlinear behavior, a negative differential conductivity, and a superlattice current oscillation, respectively.

16. The quantum dipole battery of claim 1, wherein the multilayer structure is a quantum superlattice which is composed of millions of quantum wells of superlattice minibands and quantum barriers of coherent optical phonons, wherein:
the minibands are originated from a periodicity of the superlattice and nanosized thickness of the barriers;
wavefunctions of electrons and holes are no longer localized in a certain quantum well, but exist all over the superlattice structure, but wavefunctions of the coherent optical phonons are localized in a certain barrier layer.

17. The quantum dipole battery of claim 1, wherein exciton creation in the quantum wells is induced by phonon-assisted tunneling and hopping conduction crossing the barrier layer with an external field and excitation of a valence electron leaving a hole behind, which are attractive by Coulomb force, the mechanism being strengthened by miniband formation, thermal stimulation, and/or nonadiabatic transition of a two-level system in the quantum well, the transition being induced by coherent polarized optical phonon wavefunctions, and Rabi oscillation.

18. The quantum dipole battery of claim 1, wherein excitonic transition dipoles and phonon transition dipoles are created in the superlattice with an applied electric field, and characteristics of the excitonic transition dipoles of the quantum wells are uniquely determined by specific properties of the superlattice, the transition dipole characteristic of the polarized wavefunctions of optical phonons being a unique property of the quantum barriers in the superlattice, which is induced by the applied electric field.

19. The quantum dipole battery of claim 1, wherein a charging process occurs by applying an external power through the electrodes such that supplied energy from an external power source is transferred to the quantum superlattice in the multilayer structure by means of hopping/or tunneling conduction, a nonadiabatic excitonic dipole, and/or a phonon dipole creation mechanism, and a propagation of excitonic and ionic dipolar wavefunctions, wherein a physical mechanism transferring the electric energy from the power source to the superlattice includes employing a polaronic/Wannier-Stark hopping conduction mechanism, a quantum tunneling, a nonadiabatic transition, and/or Rabi oscillation in the superlattice structure, where the electron conduction by hopping through the ionic barrier layer is assisted by an optical phonon of a coherent state and a thermal stimulation.

20. The quantum dipole battery of claim 1, wherein minibands of the quantum well in the superlattice structure is a two-level system as long as the excitonic dipole creation and annihilation are related, which are two energy eigenstates of the two-level system, the two-level system being decoupled from other degrees of freedom of the system in the quantum wells, the two-level system being a pair of conduction and valence bands which is separated from other energy bands in this specific kind of quantum superlattice so that the two-level system is feasible energetically in creation of the excitonic dipoles in the quantum wells with an applied external electric field.

21. The quantum dipole battery of claim 1, wherein valence electrons can jump to the conduction band by a nonadiabatic transition with the applied field to form the excitonic states in the two-level system by means of Rabi oscillation mechanism, excitonic state formation in the quantum wells and superlattice occurring by a hopping conduction mechanism through the barrier layer is strengthened by a thermal stimulation and the polarized optical phonon, and excitonic excitation and its propagation in the quantum superlattice structure being processed by a polaronic hopping conduction and a phonon assisted quantum tunnelling, where the excitonic wavefunctions can propagate through potential barriers from a quantum well to the next adjacent quantum well.

22. The quantum dipole battery of claim 1, wherein a coherent dipolar wavefunction in the barrier layer is a displaced vibration of the optical phonon, and an excited phonon system turns, by the applied field, eventually into a dipolar phonon system of coherent state in the barrier layers, the oscillatory evolutions of the excited and polarized ionic phonons in the barrier layers being represented as wavefunctions of quantum physics, preserving specific phase and amplitude, which is a coherent state.

23. The quantum dipole battery of claim 1, wherein transition dipole systems of coherent wavefunctions continue to propagate over the superlattice structure as energy is supplied to the system, and electronic states of two-level systems interacting with the applied electric field are excited to produce excitonic dipoles in the quantum wells of the superlattice, where transition dipole moments take supplied electric energy by a nonadiabatic process.

24. The quantum dipole battery of claim 1, wherein excitonic dipolar oscillations are vibrations of a nucleus which are due to nonadiabatic electronic transitions, which promote a dipole wavefunction of coherent state in the quantum well, and a quantum effect of the superlattice is a standing wave formation or traveling waves in the quantum wells and the quantum barriers, the wavefunctions of localized excitonic dipole moments allowing a basis for expansion of dipole states, which are collective vibrations of coherent states in the superlattice.

25. The quantum dipole battery of claim 1, wherein nonadiabatic coupling drives quantum transitions between states of a two-level system, leading to collective vibrations of an excitonic system in the quantum well, and oscillatory evolutions of the excited electrons and the holes in the quantum wells are represented as quantum coherent wavefunctions, preserving specific phase and amplitude, which is a coherent state, where eigen-modes and energy levels are quantized and size-dependent.

26. The quantum dipole battery of claim 1, wherein phonon wavefunctions of a polarized and displaced vibration which is excited by an external field are optical phonons of a coherent state, and eigen modes of the phonon are quantized in the barrier layer, which is a coherent state of a displaced harmonic oscillation, and quantum barrier layers of coherent states act as microcavities that cause confinement of the optical phonon of longitudinal mode.

27. The quantum dipole battery of claim 1, wherein confinement of coherent excitonic dipoles in the quantum well layer and a proximate location, and collective polarization ordering of the coherent optical phonon dipoles of the barrier layer, make a quantum dipole-dipole interaction viable, and specific quantum superlattice structures aid inducing coupling of coherent quantum dipoles.

28. The quantum dipole battery of claim 1, wherein collective dipole fields of coherent optical phonons of a longitudinal mode in the barrier layer are coupled to transition dipoles of excitonic vibrations of the longitudinal mode in a two-level system of the quantum wells, and transition dipoles of quantum wells and transition dipoles of barriers are coupled via quantum dipole-dipole interactions.

29. The quantum dipole battery of claim 1, wherein quantum dipole-dipole interaction between coherent excitonic wavefunctions and coherent optical phonons of longitudinal modes occurs in the heterostructures of the superlattice of the microcavity, and the interaction induces a new coupled state of exciton and phonon, the new coupled state being metastable.

30. The quantum dipole battery of claim 1, wherein stable electric nano-structures are formed in the superlattice of the multilayer structure through a structural phase transition which is caused by an excitonic-ionic wavefunction of a boson bound state in the microcavity accompanying a spontaneous structural change, the spontaneous structural change being one of a Mott-insulator or Peierls or phase transition of an electric charge system by activation of the polaronic interactions, and wherein stable electric nano-structures include at least one of a ferroelectric structure, an antiferroelectric structure, a surface exciton charge double layer structure, or an electric charge double layer structure on a boundary between the quantum well and the barrier, the supplied energy being stored as an electrostatic potential energy in the nanostructures when the battery is charged.

31. The quantum dipole battery of claim 1, wherein a transition probability amplitude of energy state in a two-level system oscillates with a Rabi frequency Q which is proportional to an amplitude of the applied field such that electronic charges of the electric dipole systems are decoupled from the ionic dipole systems and excited to the conduction bands when a high electric field \vec{E} and high power of a DC pulse or an AC applied as a trigger power for discharge.

32. The quantum dipole battery of claim 31, wherein charge carriers are released from the bound states and excited to conduction bands by the trigger power and generate voltaic power with an oscillating electric field or pulse electric field in the superlattice, and voltaic power appears on the electrodes when the battery cell is activated for discharge by the trigger power, where the trigger power is a DC pulse power of higher voltage and fast rise time, and a width of the pulse is in a range of nanosecond, the pulse being applied to the battery cell through the negative and positive electrodes for discharge, where the released power from the battery cell is harvested and fed back to the input process at a feedback device.

33. The quantum dipole battery of claim 1, wherein oscillating power or pulse shape power released from the activated battery cell is due to an applied pulse and a collectively oscillating ionic dipole field and intrinsic properties of the superlattice, the released power being rectified to DC output power and harvested, and wherein a small portion of harvested energy is fed back for the trigger pulse generation through a feedback device and remaining harvested energy is used for other works.
